(19) United States
(12) Patent Application Publication
(10) Pub. No.: US 2026/0090097 A1
(43) Pub. Date: Mar. 26, 2026

(54) Semiconductor devices and methods of manufacturing semiconductor device

(71) Applicant: Episil Technologies Inc., Hsinchu County, (TW)

(72) Inventors: YUAN LIANG LIU, HSINCHU (TW); YEN CHANG CHEN, Hsinchu (TW); YUAN CHOU CHANG, Hsinchu (TW); YI CHEN LEE, Hsinchu County, (TW)

(21) Appl. No.: 19/077,539

(22) Filed: Mar. 12, 2025

(30) Foreign Application Priority Data
Sep. 23, 2024 (TW) 113135964

(51) Int. Cl. H10D 84/85; H10D 84/01

(52) U.S. Cl. CPC H10D 84/859; H10D 84/0181; H10D 84/0186

(57) ABSTRACT

Embodiments of the present disclosure illustrates a semiconductor device. The semiconductor device comprises: a silicon carbide epitaxial layer comprising: a p-type well region; a heavily doped n-type region on a surface of the p-type well region; and a heavily doped p-type region below the heavily doped n-type region and within the p-type well region. The semiconductor device further comprises a first gate trench passing through the p-type well region; and a first deeply doped p-type region, wherein a width of the first deeply doped p-type region is narrower than a width of the first gate trench.

### BACKGROUND OF THE INVENTION

### Field of the Invention

The present invention relates to a semiconductor device, in particular relates to a power metal oxide semiconductor transistor.

### Description of the Related Art

In traditional power metal oxide semiconductor transistors, there is a high electric field at the edge of the trench, which easily leads to lower drain to source breakdown voltage (BVDSS) and reliability failure. Thus, there is a need for a new semiconductor device and a new method for manufacturing a semiconductor device to overcome the said problems.

### BRIEF SUMMARY OF THE INVENTION

In light of the previously described problems, the present disclosure provides a semiconductor device comprising: a silicon carbide epitaxial layer comprising: a p-type well region; a heavily doped n-type region on a surface of the p-type well region; and a heavily doped p-type region below the heavily doped n-type region and within the p-type well region. The semiconductor device further comprises a first gate trench passing through the p-type well region; a first deeply doped p-type region below the first gate trench; a gate oxide layer on a bottom surface and side surfaces of the first gate trench and on the heavily doped n-type region; a polysilicon layer on the gate oxide layer; an interlayer dielectric layer on the polysilicon layer; and a source trench passing through the interlayer dielectric layer and the gate oxide layer and extending into the heavily doped n-type region and the heavily doped p-type region, wherein a width of the first deeply doped p-type region is narrower than a width of the first gate trench.

The present disclosure also provides a method of manufacturing a semiconductor device comprising: providing a silicon carbide epitaxial layer, wherein a p-type well region, a heavily doped n-type region on a surface of the p-type well region, and a heavily doped p-type region below the heavily doped n-type region and within the p-type well region are predefined in the silicon carbide epitaxial layer; forming a first gate trench passing through the p-type well region in the silicon carbide epitaxial layer; forming a first deeply doped p-type region within the silicon carbide epitaxial layer below the first gate trench, wherein a width of the first deeply doped p-type region is narrower than a width of the first gate trench; forming a gate oxide layer on a bottom surface and side surfaces of the first gate trench and on the heavily doped n-type region; forming a polysilicon layer on the gate oxide layer; forming an interlayer dielectric layer on the polysilicon layer; and forming a source trench passing through the interlayer dielectric layer and the gate oxide layer and extending into the heavily doped n-type region and the heavily doped p-type region.

In summary, the high electric field at the edges of the trenches is released (or alleviated) by the first heavily doped p-type region under the first gate trench and the second heavily doped p-type region under the second gate trench, thereby enhancing the drain to source breakdown voltage (BVDSS). Additionally, the on-resistance (Rdson) can be optimized by adjusting the distance between the first and second heavily doped p-type regions. Furthermore, the junctions formed between the first and second heavily doped p-type regions and the n-type silicon carbide epitaxial layer 101 reduce the parasitic capacitance (Cgd), improving the transistor's switching speed.

### BRIEF DESCRIPTION OF THE DRAWINGS

FIG. 1 is a cross-sectional view of a semiconductor device 100 of the present disclosure.

FIG. 2 is a flow chart of a method 200 for manufacturing a semiconductor device of the present disclosure.

FIG. 3 is another cross-sectional view of the semiconductor device 100.

FIG. 4 is another cross-sectional view of the semiconductor device 100.

FIG. 5 is another cross-sectional view of the semiconductor device 100.

FIG. 6 is another cross-sectional view of the semiconductor device 100.

FIG. 7 is another cross-sectional view of the semiconductor device 100.

FIG. 8 is another cross-sectional view of the semiconductor device 100.

FIG. 9 is another cross-sectional view of the semiconductor device 100.

FIG. 10 is another cross-sectional view of the semiconductor device 100.

FIG. 11 is another cross-sectional view of the semiconductor device 100.

FIG. 12 is another cross-sectional view of the semiconductor device 100.

FIG. 13 is another cross-sectional view of the semiconductor device 100.

FIG. 14 is another cross-sectional view of the semiconductor device 100.

FIG. 15 is another cross-sectional view of the semiconductor device 100.

FIG. 16 is another cross-sectional view of the semiconductor device 100.

FIG. 17 is another cross-sectional view of the semiconductor device 100.

### DETAILED DESCRIPTION OF THE INVENTION

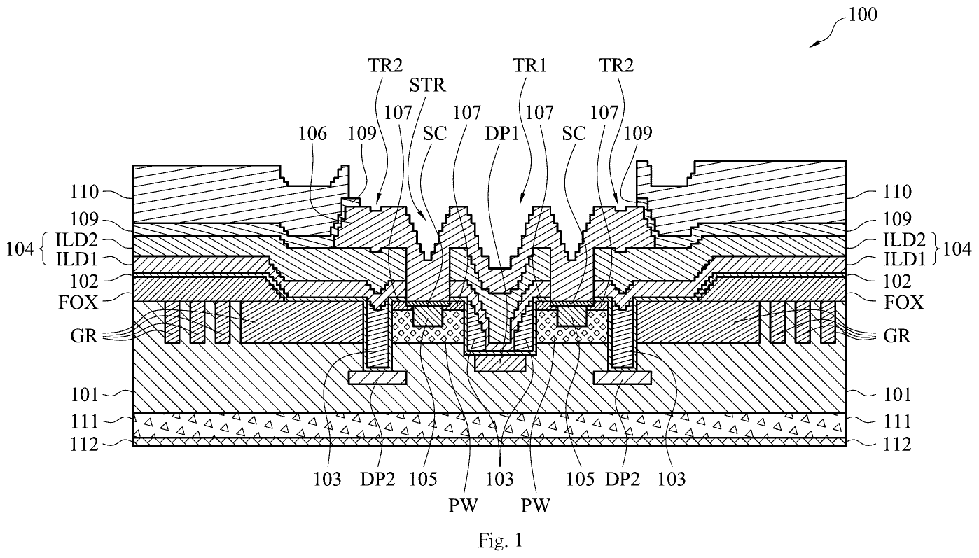

FIG. 1 is a cross-sectional view of a semiconductor device 100 of the present disclosure. As shown in FIG. 1, the semiconductor device 100 comprises a silicon carbide epitaxial layer 101, gate trenches TR1 and TR2, deeply doped p-type regions DP1 and DP2, a gate oxide layer 102, a poly silicon (polycrystalline silicon) layer 103, an interlayer dielectric layer 104 and a source trench STR. In detail, the silicon carbide epitaxial layer 101 comprises a p-type well region PW, a heavily doped n-type region 107 on the surface of the p-type well region PW, and a p-type well Heavily doped region 105 below the heavily doped n-type region 107 and within the p-type well region PW. In some embodiments, the interlayer dielectric layer 104 further includes two interlayer dielectric layers ILD1 and ILD2 for reducing unevenness caused by the trenches. In addition, the semiconductor device 100 further comprises a silicide SC, a metal layer 106 on the silicide SC, a silicon carbide substrate 111 under the silicon carbide epitaxial layer 101, and a metal layer 112 under the silicon carbide substrate 111. In detail, the metal layer 106 is in contact with the heavily doped p-type region 105 and the heavily doped n-type region 107 via the silicide SC in the source trench STR. The patterned metal layer 106 is electrically connected to the poly silicon layer 103 of the gate trenches TR1 and TR2 belonging to different transistor cells respectively to serve as gate pads, and the metal layer 106 in the source trench STR may form source pads. The composition of the metal layers 106 and 112 may include Ni, Ti, TiN, AlCu, etc., but is not limited thereto. In the preferred embodiment of the present invention, the metal layers 106 and 112 are aluminum-copper alloys.

Both the gate trenches TR1 and TR2 pass through the p-type well region PW. The deeply doped p-type region DP1 is below the gate trench TR1, and the deeply doped p-type region DP2 is below the gate trench TR2. In some embodiments, the width of the deeply doped p-type region DP1 is narrower than the width of the gate trench TR1. The gate oxide layer 102 is on the bottom surface and the side surfaces of the gate trench TR1, on the bottom surface and the side surfaces of the gate trench TR2, and on a portion of the heavily doped n-type region 107. The poly silicon layer 103 is on the gate oxide layer 102, and the interlayer dielectric layer 104 is on the poly silicon layer 103. The source trench STR passes through the interlayer dielectric layer 104 and the gate oxide layer 102 and extends into the heavily doped n-type region 107 and the heavily doped p-type region 105. As shown in FIG. 1, the gate trench TR1 and the deeply doped p-type region DP1 are included in a transistor cell, while the gate trench TR2 and the deeply doped p-type region DP2 are included within another transistor cell adjacent to the aforementioned transistor cell.

In FIG. 1, the bottom surface of the gate trench TR2 is lower than the bottom surface of the gate trench TR1, and the width of the deeply doped p-type region DP2 is wider than the width of the gate trench TR2. The gate trench The trench TR1 and the deeply doped p-type region DP1, and the gate trench TR2 and the deeply doped p-type region DP2, belong to different transistor cells, respectively.

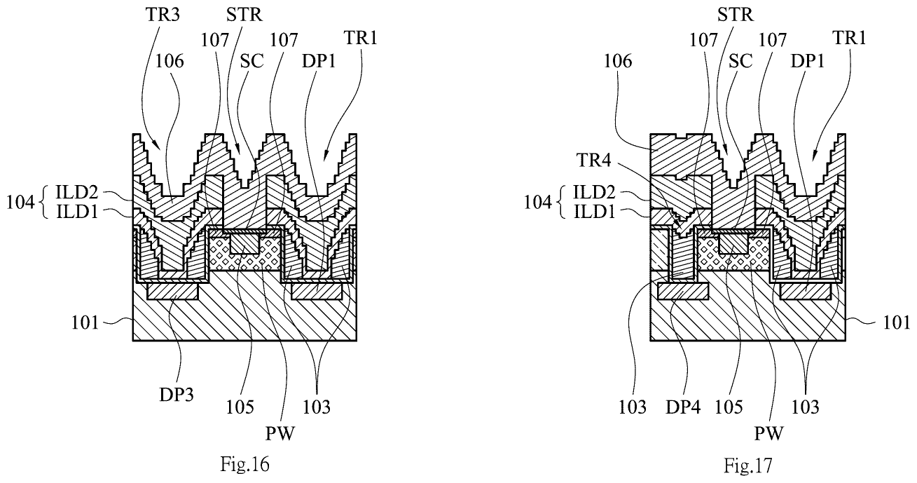

In some embodiments, the pattern of the gate trench TR2 can be replaced by the pattern of the gate trench TR1 to form the gate trench TR3 as shown in FIG. 16. In other words, the pattern of gate trench TR3 in FIG. 16 is identical to that of the gate trench TR1. Referring to FIG. 16, the bottom surface of gate trench TR3 is at the same height as the bottom surface of gate trench TR1, and the width of the bottom surface of gate trench TR3 is equal to the width of the bottom surface of gate trench TR1, so that the width of the deeply doped p-type region DP3 (which may be symmetrical to the deeply doped p-type region DP1) below the gate trench TR3 is narrower than the width of the gate trench TR3. The poly silicon layer 103 in the gate trench TR3 is cut during the etching process to expose the gate oxide layer 102 so that the interlayer dielectric layer 104 can be in contact with the gate oxide layer 102 in the gate trench TR3, as shown in FIG. 16. The gate trench TR1 and the deeply doped p-type region DP1, and the gate trench TR3 and the deeply doped p-type region DP3, may belong to different transistor cells, respectively.

In some embodiments, the pattern of the gate trench TR2 may be changed to the pattern of the gate trench TR4 as shown in FIG. 17. Referring to FIG. 17, the bottom surface of gate trench TR4 is at the same height as the bottom surface of gate trench TR1, and the width of the bottom surface of gate trench TR4 is narrower than the width of the bottom surface of gate trench TR1. Therefore, the width of the deeply doped p-type region DP4 below the gate trench TR4 (the deep doped p-type region DP4 may be the same as the deep doped p-type region DP2, with only different depths) is wider than the width of the gate trench TR4, but the interlayer dielectric layer 104 is not in contact with the gate oxide layer 102 in the gate trench TR4. The gate trench TR1 and the deeply doped p-type region DP1, and the gate trench TR4 and the deeply doped p-type region DP4, may belong to different transistor cells, respectively.

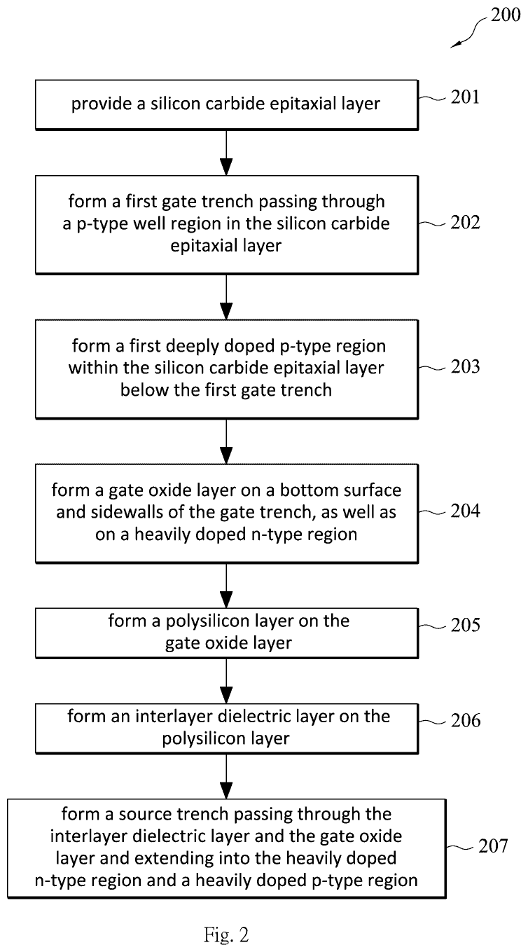

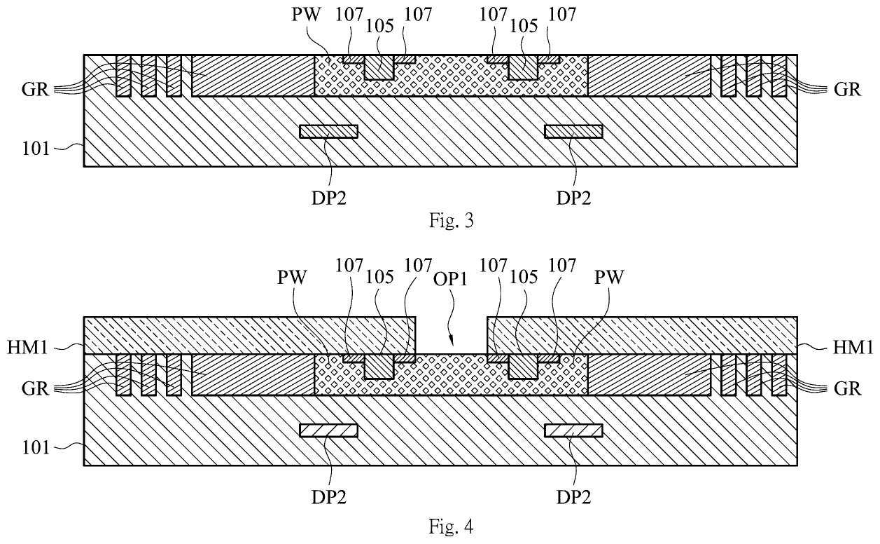

FIG. 2 is a flow chart of a method 200 of manufacturing a semiconductor device of the present disclosure, and FIGS. 3 to 15 are cross-sectional views of the semiconductor device 100 for illustrating steps 201-207 of the method 200.

First, in step 201, a silicon carbide epitaxial layer 101 is provided. As shown in FIG. 3, the p-type well region PW, the heavily doped n-type region 107 on the surface of the p-type well region PW, and the heavily doped p-type region 105 within the p-type well region and below the heavily doped n-type region 107, the guard ring region GR and the deeply doped p-type region DP2 (i.e., the second deeply doped p-type region) are predefined in the silicon carbide epitaxial layer 101. As shown in FIG. 4, a hard mask layer HM1 is deposited on the silicon carbide epitaxial layer 101, and the hard mask layer HM1 is patterned so that the opening OP1 of the patterned hard mask layer HM1 is between two heavily doped between n-type regions 107. The opening OP1 defines the area of the gate trench TR1. The step of patterning the hard mask layer HM1 comprises forming a photoresist over the hard mask layer HM1, then performing a lithography process to pattern the photoresist, performing an etching process to form the opening OP1 in the hard mask layer HM1, and then removing the photoresist.

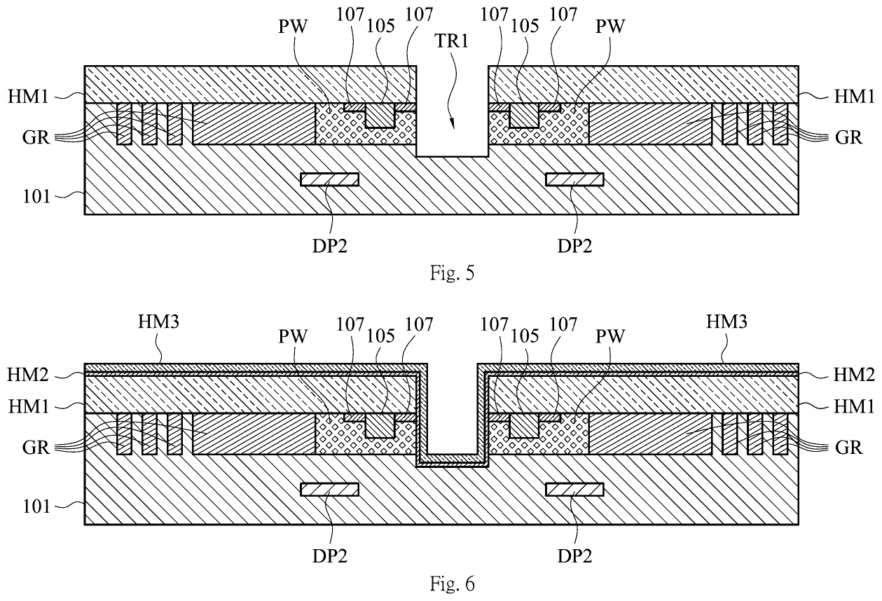

In step 202, a first gate trench passing through the p-type well region PW is formed in the silicon carbide epitaxial layer 101. As shown in FIG. 5, an etching process is performed to remove the portion of the silicon carbide epitaxial layer 101 exposed by the opening OP1 to generate the gate trench TR1 (i.e., a first gate trench) passing through the p-type well region PW. As shown in FIG. 6, a hard mask layer HM2 and a hard mask layer HM3 are sequentially deposited on the etched hard mask layer HM1, where the hard mask layer HM3 has a higher etching selectivity than the hard mask layer HM2.

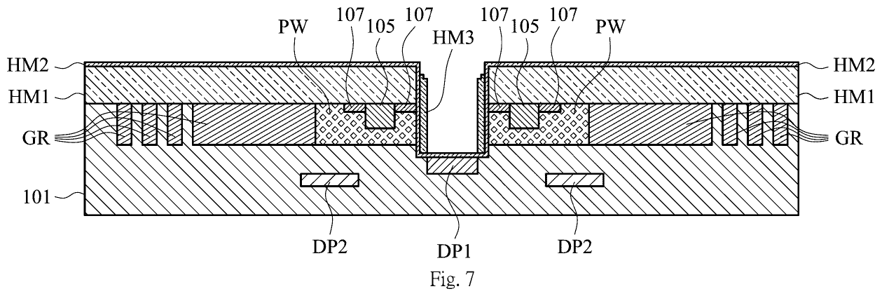

In step 203, a first deeply doped p-type region is formed within the silicon carbide epitaxial layer below the first gate trench. As shown in FIG. 7, the hard mask layer HM3 is etched back to expose the hard mask layer HM2 in the bottom of the gate trench TR1, and an ion implantation process is used to form the deeply doped p-type region DP1 (i.e., the first deeply doped p-type region) below the gate trench TR1 in the silicon carbide epitaxial layer 101. Since a portion of the hard mask layer HM3 remains in the gate trench TR1, the width of the deeply doped p-type region DP1 is smaller than the width of the gate trench TR1.

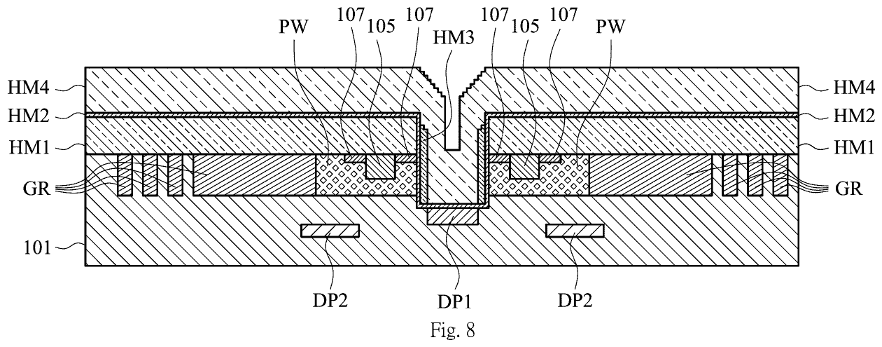

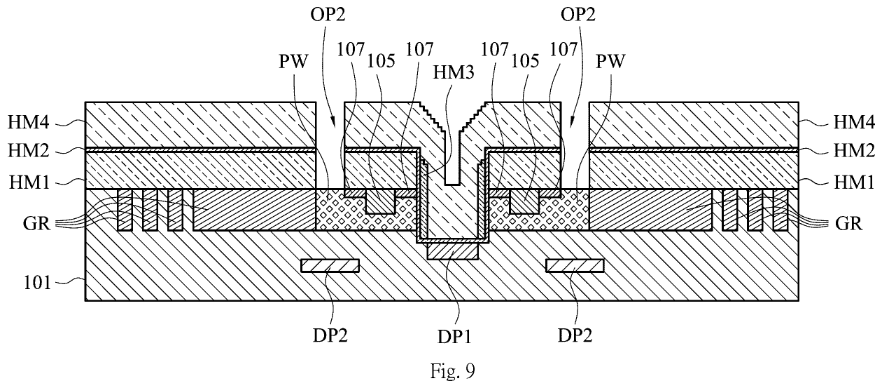

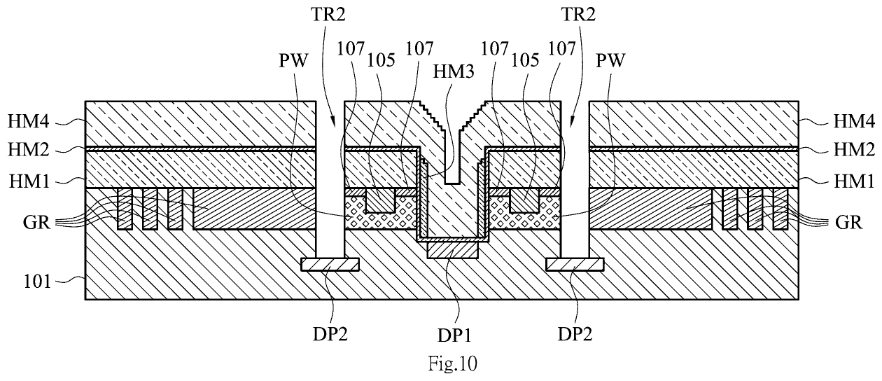

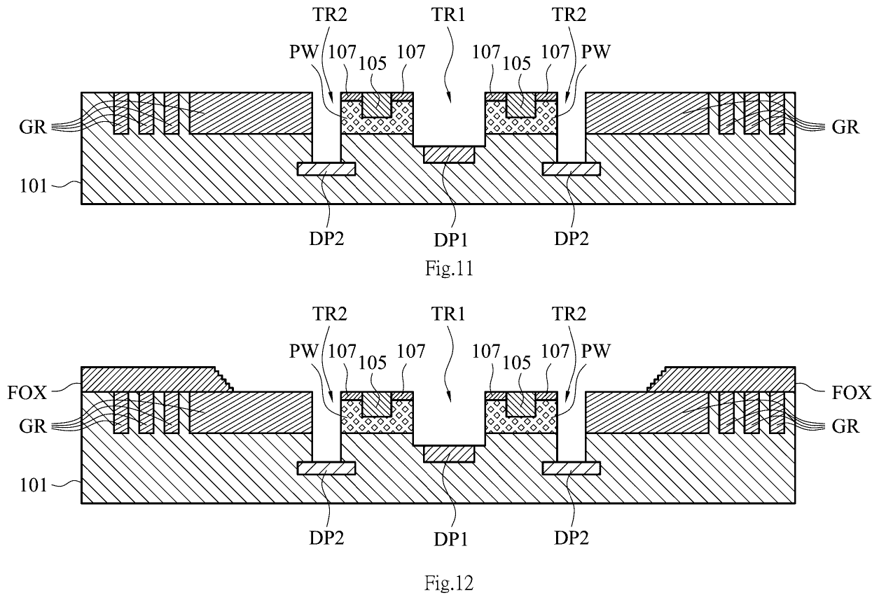

As shown in FIG. 8, a hard mask layer HM4 is deposited after performing the ion implantation process. As shown in FIG. 9, the hard mask layer HM4 is patterned to generate an opening OP2 defining an area of the gate trench TR2. The step of patterning the hard mask layer HM4 comprises forming a photoresist over the hard mask layer HM4, then performing a lithography process to pattern the photoresist, performing an etching process to form the opening OP4 in the hard mask layer HM2, and then removing the photoresist. As shown in FIG. 10, an etching process is performed to remove the portion of the silicon carbide epitaxial layer 101 exposed by the opening OP2 to generate the gate trench TR2, and the etching stops at the deeply doped p-type region DP2. The deeply doped p-type region DP2 is deeper than the deeply doped p-type region DP1. In other words, the bottom surface of the gate trench TR1 is higher than the bottom surface of the gate trench TR2. As shown in FIG. 11, the hard mask layers HM4, HM3, HM2, and HM1 are removed, and thermal annealing is performed. As shown in FIG. 12, after performing thermal annealing, an oxide is deposited and then patterned to form a field oxide layer FOX.

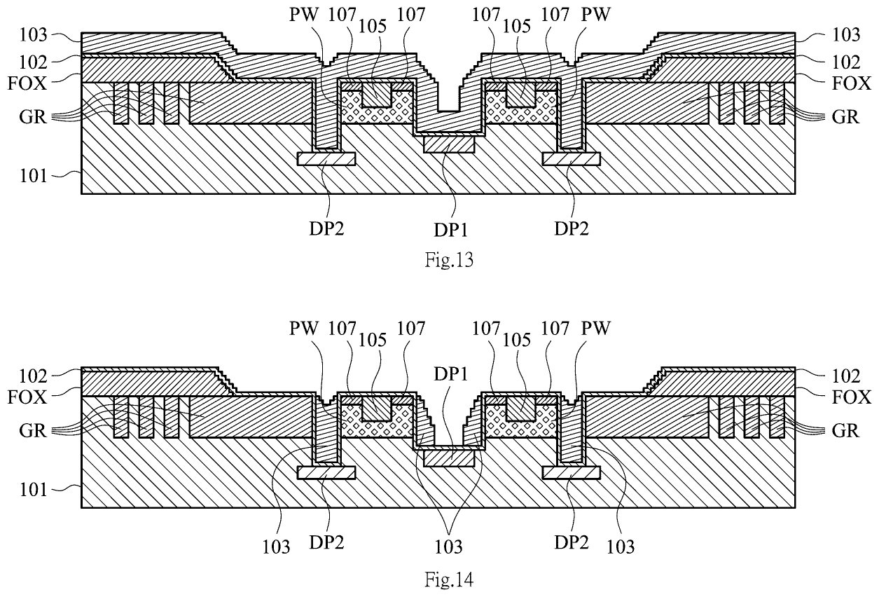

In step 204, a gate oxide layer is formed on the bottoms and the side surfaces of the first and second gate trenches, as well as on the heavily doped n-type region. In step 205, a poly silicon layer is formed on the gate oxide layer. As shown in FIG. 13, the gate oxide layer 102 is deposited, and the poly silicon layer 103 is deposited on the gate oxide layer 102. As shown in FIG. 14, a photoresist is formed on the poly silicon layer 103, and then a photolithography process is performed to pattern the photoresist, and an etching process is performed to remove the poly silicon layer 103 outside gate trench TR1 and gate trench TR2 (i.e., the second gate trench). For the gate trench TR1, although the gate oxide layer 102 is exposed at the bottom of gate trench TR1 after the poly silicon layer is etched, and the poly silicon layer 103 remains only on the sidewalls and partially on the bottom of gate trench TR1, the conduction characteristics of the semiconductor are not affected because the channel is formed on the sidewalls of gate trench TR1.

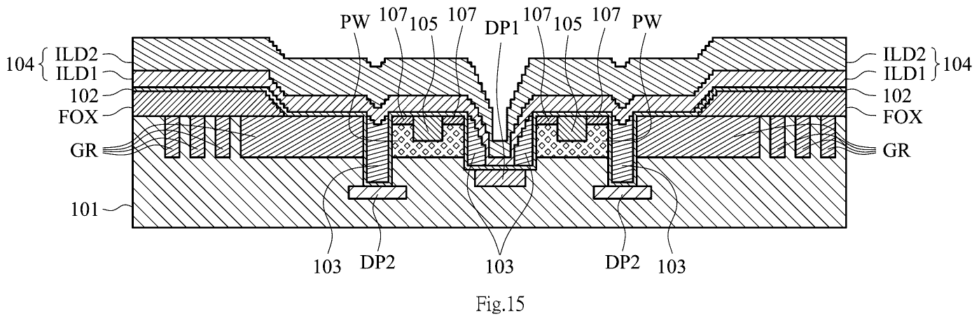

In step 206, an interlayer dielectric layer is formed on the poly silicon layer. As shown in FIG. 15, interlayer dielectric layers ILD1 and ILD2 are sequentially deposited. The interlayer dielectric layer ILD2 has a planarizing effect to reduce the height difference around the trench (e.g., the gate trench TR1).

In step 207, a source trench passing through the interlayer dielectric layer and the gate oxide layer and extending into the heavily doped n-type region and the heavily doped p-type region is formed. In detail, a photoresist is formed on the interlayer dielectric layer ILD2, then a photolithography process is performed to pattern the photoresist to form a source contact mask, and an etching process is performed to form the source trench STR passing through the interlayer dielectric layer ILD2, the interlayer dielectric layer ILD1, and the gate oxide layer 102, reaching the heavily doped n-type region 107 and the heavily doped p-type region 105. The photoresist is then removed afterward. The silicide SC is formed in the source trench STR. A patterned photoresist layer is formed by a photolithography process, an etching process is performed to generate trenches for gate pads, and the patterned photoresist layer is removed. The metal layer 106 is deposited, a patterned photoresist layer is formed by a photolithography process, and an etching process is performed to pattern the metal layer 106 to generate gate pads and source pads. The passivation layer 109 is deposited, a patterned photoresist layer is formed by a photolithography process, and an etching process is performed to pattern the passivation layer 109, so that the passivation layer 109 is formed on the metal layer 106 and the interlayer dielectric layer 104. A polyimide layer 110 may also be disposed on the passivation layer 109, as shown in FIG. 1.

In this disclosure, the high electric field at the edges of the trenches is released (alleviated) by trench by the deeply doping the p-type regions DP1 and DP2 to increase the drain to source breakdown voltage (BVDSS), and the distance between the deeply doped p-type regions DP1 and DP2 can be adjusted to optimize the on-resistance (Rdson). Furthermore, the junctions formed between the heavily doped p-type regions DP1 and DP2 and the n-type silicon carbide epitaxial layer 101 can reduce the parasitic capacitance Cgd and thereby improve the switching speed of the transistor.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device comprising:
a silicon carbide epitaxial layer comprising:
a p-type well region;
a heavily doped n-type region on a surface of the p-type well region; and
a heavily doped p-type region below the heavily doped n-type region and within the p-type well region;
a first gate trench passing through the p-type well region;
a first deeply doped p-type region below the first gate trench, wherein a width of the first deeply doped p-type region is narrower than a width of the first gate trench;
a gate oxide layer on a bottom surface and side surfaces of the first gate trench and on the heavily doped n-type region;
a polysilicon layer on the gate oxide layer;
an interlayer dielectric layer on the polysilicon layer; and
a source trench passing through the interlayer dielectric layer and the gate oxide layer and extending into the heavily doped n-type region and the heavily doped p-type region.

2. The semiconductor device of claim 1, further comprising:
a second gate trench passing through the p-type well region, wherein a bottom surface of the second gate trench is lower than the bottom surface of the first gate trench; and
a second deeply doped p-type region below the second gate trench, wherein a width of the second deeply doped p-type region is wider than a width of the second gate trench,
wherein the first gate trench and the first deeply doped p-type region, and the second gate trench and the second deeply doped p-type region, belong to different transistor cells, respectively.

3. The semiconductor device of claim 1, further comprising:
a third gate trench passing through the p-type well region, wherein a bottom surface of the third gate trench is at the same height as the bottom of the first gate trench; and
a third deeply doped p-type region below the third gate trench, wherein a width of the third deeply doped p-type region is narrower than a width of the third gate trench,
wherein the first gate trench and the first deeply doped p-type region, and the third gate trench and the third deeply doped p-type region, belong to different transistor cells, respectively.

4. The semiconductor device of claim 1, further comprising:
a fourth gate trench passing through the p-type well region, wherein a bottom surface of the fourth gate trench is at the same height as the bottom surface of the first gate trench; and
a fourth deeply doped p-type region below the fourth gate trench, wherein a width of the fourth deeply doped p-type region is wider than a width of the fourth gate trench,
wherein the first gate trench and the first deeply doped p-type region, and the fourth gate trench and the fourth deeply doped p-type region, belong to different transistor cells, respectively.

5. The semiconductor device of claim 1, further comprising:
a first metal layer in contact with the heavily doped p-type region and the heavily doped n-type region via silicide within the source trench.

6. The semiconductor device of claim 1, further comprising:
a silicon carbide substrate under the silicon carbide epitaxial layer; and
a second metal layer under the silicon carbide substrate.

7. A method for manufacturing a semiconductor device, comprising:
providing a silicon carbide epitaxial layer, wherein a p-type well region, a heavily doped n-type region on a surface of the p-type well region, and a heavily doped p-type region below the heavily doped n-type region and within the p-type well region are predefined in the silicon carbide epitaxial layer;
forming a first gate trench passing through the p-type well region in the silicon carbide epitaxial layer;
forming a first deeply doped p-type region within the silicon carbide epitaxial layer below the first gate trench, wherein a width of the first deeply doped p-type region is narrower than a width of the first gate trench;
forming a gate oxide layer on a bottom surface and side surfaces of the first gate trench and on the heavily doped n-type region;
forming a polysilicon layer on the gate oxide layer;
forming an interlayer dielectric layer on the polysilicon layer; and
forming a source trench passing through the interlayer dielectric layer and the gate oxide layer and extending into the heavily doped n-type region and the heavily doped p-type region.

8. The method of claim 7, further comprising:
forming a second gate trench passing through the p-type well region, wherein a bottom surface of the second gate trench is lower than the bottom surface of the first gate trench;
forming a second deeply doped p-type region below the second gate trench, wherein a width of the second deeply doped p-type region is wider than a width of the second gate trench,
wherein the first gate trench and the first deeply doped p-type region, and the second gate trench and the second deeply doped p-type region, belong to different transistor cells, respectively.

9. The method of claim 7, further comprising:
forming a third gate trench passing through the p-type well region, wherein a bottom surface of the third gate trench is at the same height as the bottom of the first gate trench; and
forming a third deeply doped p-type region below the third gate trench, wherein a width of the third deeply doped p-type region is narrower than a width of the third gate trench,
wherein the first gate trench and the first deeply doped p-type region, and the third gate trench and the third deeply doped p-type region, belong to different transistor cells, respectively.

10. The method of claim 7, further comprising:
forming a fourth gate trench passing through the p-type well region, wherein a bottom surface of the fourth gate trench is at the same height as the bottom surface of the first gate trench; and
forming a fourth deeply doped p-type region below the fourth gate trench, wherein a width of the fourth deeply doped p-type region is wider than a width of the fourth gate trench,
wherein the first gate trench and the first deeply doped p-type region, and the fourth gate trench and the fourth deeply doped p-type region, belong to different transistor cells, respectively.

11. The method of claim 7, further comprising:
forming a first metal layer within the source trench, wherein the first metal layer in contact with the heavily doped p-type region and the heavily doped n-type region via silicide.

12. The method of claim 7, further comprising:
forming a silicon carbide substrate under the silicon carbide epitaxial layer; and
forming a second metal layer under the silicon carbide substrate.
